(19) United States
(12) Patent Application Publication
(10) Pub. No.: US 2008/0067681 A1
(43) Pub. Date: Mar. 20, 2008

(54) INTERCONNECTION STRUCTURE AND MANUFACTURING METHOD THEREOF

(75) Inventors: Tzu-chun Tseng, Changhua County (TW); Tri-Rung Yew, Hsinchu City (TW); Chung-Min Tsai, Taipei City (TW)

Correspondence Address: J C PATENTS, INC., 4 VENTURE, SUITE 250, IRVINE, CA, 92618, US

(73) Assignee: NATIONAL TSING HUA UNIVERSITY, Hsinchu (TW)

(21) Appl. No.: 11/756,853

(22) Filed: Jun. 1, 2007

(30) Foreign Application Priority Data
Sep. 19, 2006 (TW) 95134566

(51) Int. Cl. H01L 23/52; H01L 21/4763

(52) U.S. Cl. 257/758; 438/622; 257/E23.141; 257/E21.495; 257/774

(57) ABSTRACT

An interconnection structure is provided. The interconnection structure includes a substrate, a conductive barrier layer, a dielectric layer and a carbon nanotube. A conductive region is disposed in the substrate. The conductive barrier layer is disposed over the conductive region and the conductive barrier layer includes iron, cobalt or nickel. The dielectric layer is disposed on the substrate. The carbon nanotube is disposed in the dielectric layer to electrically connect with the conductive barrier layer.

### CROSS-REFERENCE TO RELATED APPLICATION

This application claims the priority benefit of Taiwan application serial no. 95134566, filed Sep. 19, 2006. All disclosure of the Taiwan application is incorporated herein by reference.

### BACKGROUND OF THE INVENTION

1. Field of the Invention

The present invention relates to an integrated circuit (IC) structure and the fabrication method thereof. More specifically, the present invention relates to an interconnection structure and a fabrication method thereof.

2. Description of Related Art

Highly integrated semiconductor components generally have more than one layer of interconnection metal layer, called multilevel interconnects, so as to adapt to the tridimensional wiring structure due to the increased density of components.

FIG. 1A is a cross section diagram of a known interconnection structure. With reference to FIG. 1A, the interconnection 10a includes a substrate 100, a copper wire 102, a metal barrier layer 104, a silicon nitride layer 106, a dielectric layer 108 and a copper plug 110. The copper wire 102 is disposed in the substrate 100. The dielectric layer 108 is disposed on the substrate 100. The silicon nitride barrier layer 106 is disposed between the dielectric layer 108 and the substrate 100. An opening 109 passing through the silicon nitride barrier layer 106 and the dielectric layer 108 exposes a portion of the copper wire 102. The copper plug 110 is disposed in the opening 109 and is electrically connected to the copper wire 102. The metal barrier layer 104 is disposed between the copper plug 110 and the side wall and bottom of the opening 109, and between the substrate 100 and the copper wire 102.

Since the silicon nitride barrier layer 106 has a higher dielectric constant, RC delay may be incurred. In order to resolve this problem, generally a CoWP (cobalt tungsten phosphide) layer is disposed on the surface of the copper wire 102 to replace the silicon nitride barrier layer 106 which has a higher dielectric constant. FIG. 1B is a cross-section view of another conventional interconnection structure. Referring to FIG. 1B, the interconnection structure 10b comprises the substrate 100, the copper wire 102, the dielectric layer 108, the copper plug 110 and the CoWP layer 112. The copper wire 102 is disposed in the substrate 100. The CoWP layer 112 is disposed on the copper wire 102. The dielectric layer 108 is disposed on the substrate 100. The opening 109 is formed in the dielectric layer 108, wherein a portion of the CoWP layer 112 is exposed by the opening 109. The copper plug 110 is disposed in the opening 109 and is electrically connected to the CoWP layer 112. The metal barrier layer 104 is disposed between the copper plug 110 and the side wall and bottom of the opening 109, and between the substrate 100 and the copper wire 102.

However, along with the development of science and technology, the size of IC is getting smaller and smaller, and the diameter of the opening 109 is also correspondingly reduced. When the diameter of the opening 109 becomes smaller and smaller, the current flowing through unit area in the copper plug 110 becomes larger and larger, and the large flow of current may damage components and the reliability of components is reduced. In addition, the material of the metal barrier layer 104 is typically Ta/TaN, Ta or TaN, so that the resistance of the metal barrier layer 104 is higher than that of the copper plug 110. Therefore, when the size of a component is reduced, the ratio of metal barrier layer 104 vs the copper plug 110 is correspondingly increased, which causes the problem of increased plug resistance.

In addition, a carbon nanotube (CNT) can also be used to replace the copper plug 110. The efficiency of the interconnection structure is improved by using the CNT that can withstand high current density (1000 times higher than that of copper). FIG. 1C is a cross-section view of another conventional interconnection structure. Referring to FIG. 1C, the interconnection structure 10C comprises the substrate 100, the copper wire 102, the metal barrier layer 104, the dielectric layer 108, the Ta barrier layer 114, the cobalt (Co) (or Ni, Nickel) metal layer 116 and the CNT 118. The copper wire 102 is disposed in the substrate 100. The metal barrier layer 104 is disposed between the substrate 100 and the copper wire 102. The dielectric layer 108 is disposed on the substrate 100. The Ta barrier layer 114 is disposed between the dielectric layer 108 and the substrate 100. An opening 109 is formed in the dielectric layer 108, wherein the opening 109 exposes a portion of the Ta barrier layer 114. The Co (or Ni) metal layer 116 is disposed in the opening 109 and on top of the Ta barrier layer 114. The CNT 118 is disposed in the opening 109 and on top of the Co(or Ni) metal layer 116.

However, in the interconnection structure 10c, the Ta barrier layer 114 is a conductive layer, and is formed on a whole chip via a deposition process. Therefore the copper wire 102 under the Ta barrier layer 114 may be electrically connected to the conductive structure of other regions and cause short circuit. However, due to the high density of components, it is impossible to pattern the Ta barrier layer 114 on a chip accurately. Therefore the interconnection structures 10c can not be mass produced. In addition, in order to form the CNT 118 in the opening, the Co(or Ni) metal layer 116 used as a catalyst has to be formed first, which makes the fabricating process more complicated and more difficult, and the manufacturing cost is increased.

### SUMMARY OF THE INVENTION

The present invention is directed to an interconnection structure that can improve component efficiency and increase the reliability.

The present invention is also directed to a simple method for fabricating the interconnection structure that can reduce the fabrication cost.

The present invention provides an interconnection structure which includes a substrate, a conductive barrier layer, a dielectric layer and a carbon nanotube (CNT). The substrate has a conductive region. The conductive barrier layer is disposed on the conductive region, and may be comprised of Fe (iron), Co (cobalt) or Ni (nickel). The dielectric layer is disposed on the substrate. The CNT is disposed in the dielectric layer and is electrically connected to the conductive barrier layer.

According to an embodiment of the present invention, the material of the above conductive barrier layer comprises, for example, Fe, Co or Ni base compound.

According to an embodiment of the present invention, the material of the conductive barrier layer comprises, for example, CoWP, NiWP, CoWB, NiWB, CoMoP, NiMoP or the derivatives thereof.

According to an embodiment of the present invention, the material of the conductive barrier layer comprises, for example, CoWP, and the thickness of the conductive barrier layer is, for example, between 5 nm to 20 nm.

According to an embodiment of the present invention, the conductive region comprises, for example, a copper wire.

According to an embodiment of the present invention, the material of the above dielectric layer comprises, for example, silicon dioxide or an insulating material with a low dielectric constant.

According to an embodiment of the present invention, a barrier layer may be disposed between the conductive region and the substrate.

According to an embodiment of the present invention, the material of the barrier layer comprises, for example, Ta/TaN, CoWP, NiWP, CoWB, NiWB, CoMoP or NiMoP.

The present invention provides a method for fabricating an interconnection structure. First, a substrate having a conductive region formed therein is provided. Next, a conductive barrier layer is formed over the conductive region, wherein the conductive barrier layer may be comprised of Fe, Co or Ni. Next, a dielectric layer is formed over the substrate. Next a CNT is formed in the dielectric layer, and is electronically connected to the conductive barrier layer.

According to an embodiment of the present invention, the material of the conductive barrier layer comprises, for example, Fe, Co or Ni base compound.

According to an embodiment of the present invention, the material of the conductive barrier layer comprises, for example, CoWP, NiWP, CoWB, NiWB, CoMoP NiMoP or derivatives thereof.

According to an embodiment of the present invention, the material of the conductive barrier layer comprises, for example, CoWP, and the thickness of the conductive barrier layer is, for example, between 5 nm to 20 nm.

According to an embodiment of the present invention, the method of forming the conductive barrier layer comprises, for example, an electroless plating process.

According to an embodiment of the present invention, the method of forming the CNT comprises, for example, a chemical vapor deposition process.

According to an embodiment of the present invention, the process temperature is, for example, between 300° C. to 450° C., and a pressure is, for example, between 1 torr to 20 torr, and in an atmosphere of the gas including, for example, C₂H₂, H₂ and Ar for forming the CNT.

According to an embodiment of the present invention, the flow rate of the C₂H₂ is, for example, between 1 sccm to 100 sccm.

According to an embodiment of the present invention, the flow rate of the H₂ is, for example, between 100 sccm to 500 sccm.

According to an embodiment of the present invention, the flow rate of Ar gas is, for example, between 0 sccm to 500 sccm.

During the fabrication process of the interconnection structure of the present invention, since the CNT is directly formed on the conductive barrier layer comprising Fe, Co or Ni which is used to form the CNT, therefore the step of forming the catalyst layer may be eliminated. Thus, the fabrication process is simplified. And, since the conductive barrier layer is formed using an electroless plating process, and therefore no additional patterning process is required to remove the conductive barrier layer on other area on the chip. Therefore, the object of mass production can be achieved.

In addition, the present invention uses the CNT which has the advantageous feature of high conductivity, and comprises CoWP and the alike serving as the conductive barrier layer, and therefore the reliability of components can be effectively increased.

In order to make the aforementioned and other objects, features and advantages of the present invention comprehensible, a preferred embodiment accompanied with figures is described in detail below.

### BRIEF DESCRIPTION OF THE DRAWINGS

FIG. 1A is a cross-section view of a conventional interconnection structure.

FIG. 1B is a cross-section view of another conventional interconnection structure.

FIG. 1C is a cross-section view of yet another conventional interconnection structure.

FIG. 2A to FIG. 2C are schematic cross-section views illustrating a process for fabricating the interconnection structure according to an embodiment of the present invention.

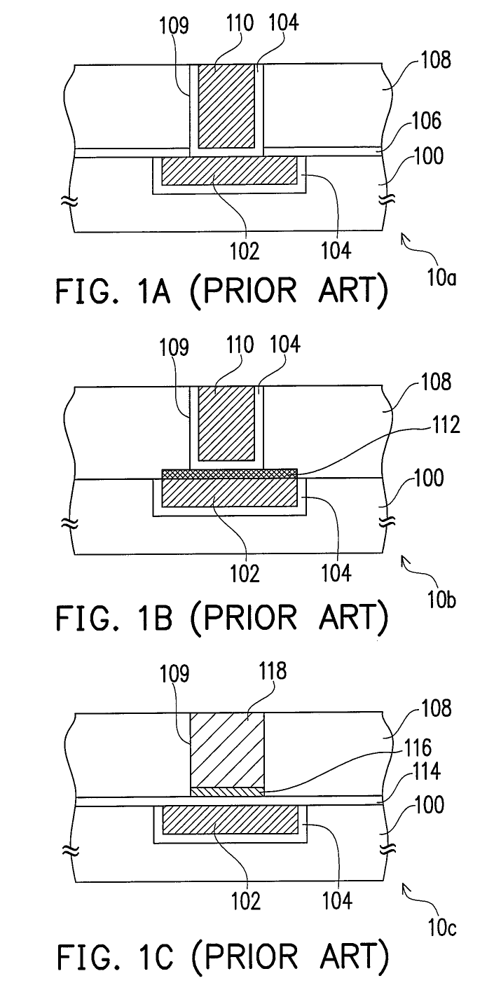

### DESCRIPTION OF THE EMBODIMENTS

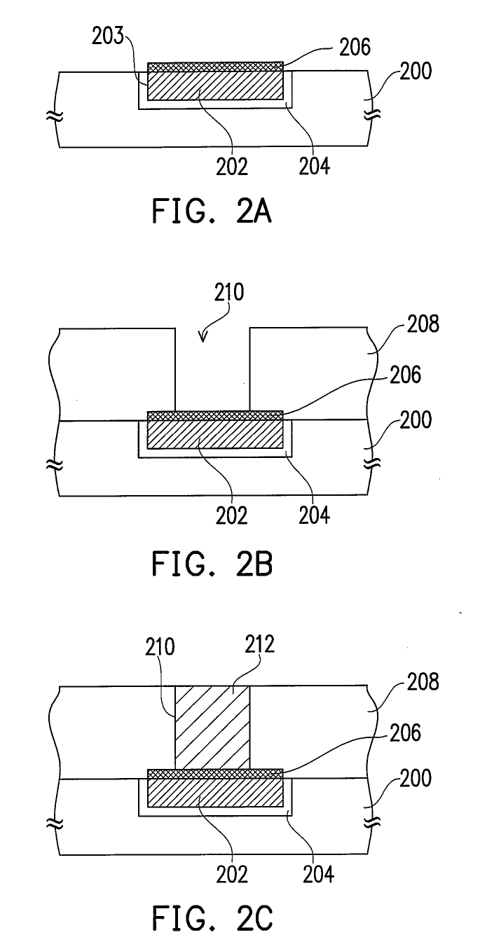

FIG. 2A to FIG. 2C are schematic cross-section views illustrating the method for fabricating the interconnection structure according to an embodiment of the present invention. First, referring to FIG. 2A, the substrate 200 having the conductive region 202 formed therein is provided. The conductive region 202 comprises, for example, a copper wire, and the forming method thereof for example is to perform Photo Lithography and etching process to the substrate 200 to form the opening 203 in the substrate 200. Next, a copper metal layer (not shown) is deposited over the substrate 200 to fill into the opening 203. Next, the portion of the copper metal layer disposed outside the opening 203 is removed through a Chemical Mechanical Polishing (CMP) process. In addition, before the copper metal layer is deposited, the barrier layer 204 can be selectively formed on the side wall and the bottom of the opening 203. The material of the barrier layer 204 comprises, for example, Ta, TaN, Ta/TaN, CoWP, NiWP, CoWB, NiWB, CoMoP or NiMoP.

Still referring to FIG. 2A, the conductive barrier layer 206 is formed on the conductive region 202. The material of the conductive barrier layer 206 comprises, for example, Fe, Co or Ni base compound. Thus, the conductive barrier layer 206 being used as a barrier layer of the conductive region 202, the conductive barrier layer 206 can also serve as the catalyst which is needed during the subsequent formation of CNT. The material of the conductive barrier layer 206 comprises, for example, CoWP, NiWP, CoWB, NiWB, CoMoP NiMoP or the derivatives thereof. The conductive barrier layer 206 may be formed by performing, for example, an electronless plating process. When the material of the conductive barrier layer 206 is CoWP, the thickness thereof is, for example, between 5 nm to 20 nm.

It should be noted that since the conductive barrier layer 206 is formed on the conductive region 202 using electroless plating process, therefore the conductive barrier layer 206 will not be formed on other areas on the chip. That is, additional patterning process which is used to remove the conductive barrier layer 206 of other areas on the chip in the prior art is not required. Therefore the mass production under high component density is possible.

Next, referring to FIG. 2B, the dielectric layer 208 is formed on the substrate 200. The material of the dielectric layer 208 comprises, for example, silicon oxide or insulating materials with low dielectric constant. Photo lithography and etching process may be performed to form the opening 210 in the dielectric layer 208. The opening 210 exposes a portion of the conductive barrier layer 206.

Next, referring to FIG. 2C, the CNT 212 is formed in the dielectric layer 208, and the CNT 212 is electrically connected to the conductive barrier layer 206. The CNT 212 may be formed by performing, for example, a chemical vapor deposition process. More specifically, the CNT 212 is formed, for example, at a process temperature between 300° C. to 450° C., and at a pressure, for example, between 1 torr to 20 torr, and in an atmosphere of the gas including, for example, C₂H₂, H₂ and Ar wherein the flow rate of the C₂H₂ is, for example, between 1 sccm to 100 sccm, the H₂ flow rate is, for example, between 100 sccm to 500 sccm, and the Ar flow rate is, for example, between 0 sccm to 500 sccm. In a preferred embodiment, the temperature is, for example, between 380° C. to 410° C., and the pressure is, for example, between 5 torr to 10 torr, the C₂H₂ flow rate is, for example, between 1 sccm to 60 sccm, the H₂ flow rate is, for example, between 100 sccm to 500 sccm, the Ar flow rate is, for example, between 0 sccm to 450 sccm. More preferably, the temperature is, for example, 400° C., the pressure is, for example, 10 torr, and the flow ratio of C₂H₂ to H₂ is, for example, 7:500.

It should be noted that as the barrier layer of the conductive region 202, the conductive barrier layer 206 already comprises the catalyst which is needed when forming the CNT 212, so it is not necessary to form an additional catalyst layer before forming the CNT 212, therefore the fabrication process is simplified and the manufacturing cost is reduced.

The interconnection structure of the present invention will be described below with reference to FIG. 2C as an example.

Referring to FIG. 2C, the interconnection structure of the present invention comprises the substrate 200, the conductive region 202, the conductive barrier layer 206, the dielectric layer 208 and the CNT 212. The conductive region 202 is disposed in the substrate 200. The conductive barrier layer 206 is disposed on the conductive region 202, and comprises Fe, Co or Ni used to form the CNT 212. The dielectric layer 208 is disposed on the substrate 200. The CNT 212 is disposed in the dielectric layer 208 and is electrically connected to the conductive barrier layer 206. In addition, the barrier layer 204 is selectively disposed between the conductive region 202 and the substrate 200.

In the present embodiment, the CTN 212 is directly disposed on the conductive barrier layer 206 which comprises Fe, Co or Ni used to form the CTN 212. In the meantime, the conductive barrier layer 206 is used as the barrier layer of the conductive region 202, and therefore problems due to RC delay may be effectively avoided, and the CNT 212 is used as the plug in the interconnection structure of the present invention to reduce the resistance, and the reliability of the component can be increased. Since the need for an additional catalyst layer can be eliminated, the manufacturing cost can be effectively reduced.

To sum up, in the interconnection structure of the present invention, the CNT is directly formed on the conductive barrier layer comprising Fe, Co or Ni used to form the CNT, therefore the a process step of forming the catalyst layer of the CNT can be eliminated, and therefore the fabrication process is simplified. Furthermore, the conductive barrier layer is formed using an electroless plating process, and therefore there is no need to remove the conductive barrier layer on other areas on the chip through an extra patterning process, and the object of mass production can be achieved. In addition, the CNT, which can withstand high current density, is used as the plug of the interconnection structure, and a material comprising CoWP and the alike is used as the conductive barrier layer, and therefore the reliability of the component can be effectively increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An interconnection structure, comprising:
a substrate, comprising a conductive region;
a conductive barrier layer, disposed over the conductive region, and the conductive barrier layer containing Fe, Co or Ni;
a dielectric layer, disposed over the substrate; and
a carbon nanotube (CNT), disposed in the dielectric layer and being electrically connected to the conductive barrier layer.

2. The interconnection structure of claim 1, wherein the conductive barrier layer comprises Fe, Co or Ni based compound.

3. The interconnection structure of claim 2, wherein the conductive barrier layer comprises CoWP, NiWP, CoWB, NiWB, CoMoP, NiMoP or derivatives thereof.

4. The interconnection structure of claim 3, wherein the conductive barrier layer comprises CoWP, and the thickness of the conductive barrier layer is in a range between 5 nm to 20 nm.

5. The interconnection structure of claim 1, wherein the conductive region comprises a copper wire.

6. The interconnection structure of claim 1, wherein the dielectric layer comprises silicon dioxide or insulating material with a dielectric constant substantially equivalent or lower than that of silicon dioxide.

7. The interconnection structure of claim 1, further comprising a barrier layer disposed between the conductive region and the substrate.

8. The interconnection structure of claim 7, wherein the barrier layer comprises Ta/TaN, CoWP, NiWP, CoWB, NiWB, CoMoP or NiMoP.

9. A method of fabricating an interconnection structure, comprising:
providing a substrate comprising a conductive region formed therein;
forming a conductive barrier layer over the conductive region, and the conductive barrier layer containing Fe, Co or Ni;
forming a dielectric layer over the substrate; and
forming a CNT in the dielectric layer electrically connected to the conductive barrier layer.

10. The method of fabricating an interconnection structure of claim 9, wherein the conductive barrier layer comprises Fe, Co or Ni base compound.

11. The method of fabricating an interconnection structure of claim 10, wherein the conductive barrier layer comprises CoWP, NiWP, CoWB, NiWB, CoMoP, NiMoP or derivatives thereof.

12. The method of fabricating an interconnection structure of claim 11, wherein the conductive barrier layer comprises CoWP, and the thickness thereof is in a range between 5 nm to 20 nm.

13. The method of fabricating an interconnection structure of claim 9, wherein the conductive barrier layer formed by performing an electroless plating process.

14. The method of fabricating an interconnection structure of claim 9, wherein the CNT is formed by performing a chemical vapor deposition process.

15. The method of fabricating an interconnection structure of claim 14, wherein the chemical vapor deposition process is carried out at a process temperature in a range between 300° C. to 450° C., a pressure in a range between 1 torr to 20 torr, and in an atmosphere of the gas including C₂H₂, H₂ and Ar.

16. The fabrication method of the interconnection structure of claim 15, wherein the flow rate of C₂H₂ is between 1 sccm to 100 sccm.

17. The method of fabricating an interconnection structure of claim 15, wherein a flow rate of H₂ is in a range between 100 sccm to 500 sccm.

18. The method of fabricating an interconnection structure of claim 15, wherein a flow rate of Ar is in a range between 0 sccm to 500 sccm.

19. The method of fabricating an interconnection structure of claim 9, wherein the conductive region comprises a copper wire.

20. The method of fabricating an interconnection structure of claim 9, wherein the dielectric layer comprises silicon dioxide or insulating material with a dielectric constant substantially equivalent or lower than that of silicon dioxide.
